(19) United States
(12) Patent Application Publication
(10) Pub. No.: US 2015/0270844 A1
(43) Pub. Date: Sep. 24, 2015

(54) ATOM CELL, QUANTUM INTERFERENCE DEVICE, ATOMIC OSCILLATOR, ELECTRONIC APPARATUS, AND MOVING OBJECT

(71) Applicant: Seiko Epson Corporation, Tokyo (JP)

(72) Inventors: Yoshiyuki MAKI, Suwa (JP); Takuya NAKAJIMA, Ushiku (JP)

(21) Appl. No.: 14/662,588

(22) Filed: Mar. 19, 2015

(30) Foreign Application Priority Data
Mar. 20, 2014 (JP) 2014-058506

(51) Int. Cl. H03L 7/26

(52) U.S. Cl. CPC H03L 7/26

(57) ABSTRACT

A gas cell according to an embodiment includes an alkali metal, a space S1 in which a gaseous alkali metal is enclosed, a space S2 in which a liquid-state or a solid-state alkali metal is arranged, and a space S3 which connects the space S1 and the space S2 and has a portion with a smaller width than the space S2.

### BACKGROUND

1. Technical Field

The present invention relates to an atom cell, a quantum interference device, an atomic oscillator, an electronic apparatus, and a moving object.

2. Related Art

An atomic oscillator that oscillates based on the energy transition of atoms of alkali metal, such as rubidium and cesium, has been known as an oscillator which has high-accuracy oscillation characteristics for a long period of time.

In general, the operating principle of the atomic oscillator is mainly divided into a type using a double resonance phenomenon caused by light and microwaves and a type using the coherent population trapping (CPT) caused by two types of light components with different wavelengths.

In general, in any type of atomic oscillator, a gas cell (atom cell) is heated to a predetermined temperature by a heater in order to enclose an alkali metal in the gas cell and to maintain the alkali metal in a gas state.

In general, in the gas cell, all of the alkali metal is not gasified, but a part of the alkali metal is liquefied as a surplus. The surplus alkali metal atoms are precipitated (condensed) in a low-temperature portion of the gas cell and are liquefied. When the surplus alkali metal atoms are present in an excitation light passage region, they block the excitation light. As a result, the oscillation characteristics of the atomic oscillator deteriorate.

Therefore, in a gas cell according to JP-A-2010-205875, a concave portion for precipitating alkali metal is provided in the inner wall surface of the gas cell.

However, in the gas cell according to JP-A-2010-205875, surplus alkali metal which is precipitated in the concave portion faces the excitation light passage region at a relatively short distance and the state of the surplus alkali metal is changed over time due to, for example, thermal diffusion. Therefore, a part of the excited gaseous alkali metal comes into contact with the surplus alkali metal in the concave portion and the excited gaseous alkali metal changes to a non-uniform state. As a result, the oscillation characteristics deteriorate (for example, a frequency variation occurs).

### SUMMARY

An advantage of some aspects of the invention is to provide an atom cell which can suppress deterioration of characteristics due to a surplus metal atom and a quantum interference device, an atomic oscillator, an electronic apparatus, and a moving object which include the atom cell.

The invention can be implemented as the following forms or application examples.

### Application Example 1

An atom cell according to this application example includes: metal; a light passage portion in which the metal in a gas state is enclosed; a metal reservoir portion in which the metal in a liquid state or a solid state is arranged; and a connection portion that connects the light passage portion and the metal reservoir portion and has a part with a smaller width than the metal reservoir portion.

According to the atom cell, since the connection portion has a part with a smaller width than the metal reservoir portion, it is possible to reduce the movement of the liquid-state metal in the metal reservoir portion to the light passage portion (to stabilize the behavior of the liquid-state metal) and to reduce the influence of the liquid-state metal on gaseous metal in the light passage portion, while ensuring the size of the metal reservoir portion. As a result, it is possible to suppress deterioration of characteristics due to surplus metal.

### Application Example 2

It is preferable that the atom cell according to the application example further includes: a pair of window portions; and a body portion that is provided between the pair of window portions, forms the light passage portion together with the pair of window portions, and includes the metal reservoir portion and the connection portion.

According to this configuration, it is possible to simply form a small atom cell including the light passage portion, the metal reservoir portion, and the connection portion with high accuracy.

### Application Example 3

In the atom cell according to the application example, it is preferable that the connection portion has a part with a smaller width than the metal reservoir portion, as viewed from a direction in which the pair of window portions overlap each other.

According to this configuration, it is possible to form the connection portion in the entire region between the pair of window portions. Therefore, the symmetry of the spectrum shape of a resonance signal is improved, which makes it possible to improve the stability of the frequency. In addition, it is possible to form the body portion including the connection portion with a smaller width than the metal reservoir portion, using a simple method which forms a through hole in a substrate so as to pass through the substrate in the thickness direction.

### Application Example 4

In the atom cell according to the application example, it is preferable that the connection portion has a part with a width that is equal to or less than one-fifth of the width of the light passage portion, as viewed from a direction in which the pair of window portions overlap each other.

According to this configuration, it is possible to effectively reduce the influence of the liquid-state metal in the metal reservoir portion on the gaseous metal in the light passage portion.

### Application Example 5

In the atom cell according to the application example, it is preferable that the connection portion has a part with a smaller width than the metal reservoir portion, as viewed from a direction perpendicular to a direction in which the pair of window portions overlap each other.

According to this configuration, it is possible to increase the distance between an opening of the connection portion close to the light passage portion and at least one of the pair of window portions. Therefore, it is possible to effectively reduce the movement of the liquid-state metal to the window portion. As a result, it is possible to effectively suppress deterioration of characteristics due to surplus metal.

### Application Example 6

In the atom cell according to the application example, it is preferable that the body portion and the window portion are heated and bonded to each other.

According to this configuration, it is possible to airtightly bond the body portion and each window portion with a relatively simple structure.

### Application Example 7

In the atom cell according to the application example, it is preferable that the body portion includes silicon.

According to this configuration, it is possible to form the light passage portion, the metal reservoir portion, and the connection portion with high accuracy, using a MEMS processing technique, and to reduce the size of the atom cell.

### Application Example 8

In the atom cell according to the application example, it is preferable that a distance between the light passage portion and the metal reservoir portion along the connection portion is greater than the width of the connection portion.

According to this configuration, it is possible to effectively reduce the influence of the liquid-state metal in the metal reservoir portion on the gaseous metal in the light passage portion.

### Application Example 9

In the atom cell according to the application example, it is preferable that the distance between the light passage portion and the metal reservoir portion along the connection portion is equal to or greater than two times the width of the connection portion.

According to this configuration, it is possible to effectively reduce the influence of the liquid-state metal in the metal reservoir portion on the gaseous metal in the light passage portion.

### Application Example 10

A quantum interference device according to this application example includes the atom cell according to the application example.

According to this configuration, it is possible to provide a quantum interference device including an atom cell which can suppress deterioration of characteristics due to surplus metal atom.

### Application Example 11

An atomic oscillator according to this application example includes the atom cell according to the application example.

According to this configuration, it is possible to provide an atomic oscillator including an atom cell which can suppress deterioration of characteristics due to surplus metal atom.

### Application Example 12

An electronic apparatus according to this application example includes the atom cell according to the application example.

According to this configuration, it is possible to provide an electronic apparatus including an atom cell which can suppress deterioration of characteristics due to surplus metal atom.

### Application Example 13

A moving object according to this application example includes the atom cell according to the application example.

According to this configuration, it is possible to provide a moving object including an atom cell which can suppress deterioration of characteristics due to surplus metal atom.

### BRIEF DESCRIPTION OF THE DRAWINGS

The invention will be described with reference to the accompanying drawings, wherein like numbers reference like elements.

FIG. 1 is a schematic diagram illustrating an atomic oscillator (quantum interference device) according to a first embodiment of the invention.

FIG. 2 is a diagram illustrating the energy state of alkali metal.

FIG. 3 is a graph illustrating the relationship between a frequency difference between two light components emitted from a light emitting unit and the intensity of light detected by a light detection unit.

FIG. 4 is a perspective view illustrating an atom cell included in the atomic oscillator illustrated in FIG. 1.

FIG. 5A is a horizontal cross-sectional view illustrating the atom cell illustrated in FIG. 4.

FIG. 5B is a vertical cross-sectional view illustrating the atom cell illustrated in FIG. 4.

FIG. 6A is a graph illustrating the relationship between the stability of the frequency and the ratio (W2/W) of the width W2 of a connection portion to the width W of a light passage portion.

FIG. 6B is a graph illustrating the relationship between the stability of the frequency and the ratio (L/W2) of a distance L between the light passage portion and a metal reservoir portion along the connection portion to the width W2 of the connection portion.

FIG. 7 is a horizontal cross-sectional view illustrating an atom cell according to a second embodiment of the invention.

FIG. 8 is a horizontal cross-sectional view illustrating an atom cell according to a third embodiment of the invention.

FIG. 9 is a horizontal cross-sectional view illustrating an atom cell according to a fourth embodiment of the invention.

FIG. 10 is a horizontal cross-sectional view illustrating an atom cell according to a fifth embodiment of the invention.

FIG. 11 is a horizontal cross-sectional view illustrating an atom cell according to a sixth embodiment of the invention.

FIG. 12 is a perspective view illustrating an atom cell according to a seventh embodiment of the invention.

FIG. 13 is a diagram illustrating a schematic structure when the atomic oscillator according to the invention is used in a positioning system using a GPS satellite.

FIG. 14 is a diagram illustrating an example of a moving object according to the invention.

### DESCRIPTION OF EXEMPLARY EMBODIMENTS

Hereinafter, an atom cell, a quantum interference device, an atomic oscillator, an electronic apparatus, and a moving object according to the invention will be described in detail with reference to embodiments illustrated in the accompanying drawings.

### 1. Atomic Oscillator (Quantum Interference Device)

First, an atomic oscillator according to the invention (an atomic oscillator including a quantum interference device according to the invention) will be described. Hereinafter, an example in which the quantum interference device according to the invention is applied to the atomic oscillator will be described. However, the application of the quantum interference device according to the invention is not limited thereto. For example, the quantum interference device according to the invention can be applied to a magnetic sensor and a quantum memory in addition to the atomic oscillator.

### First Embodiment

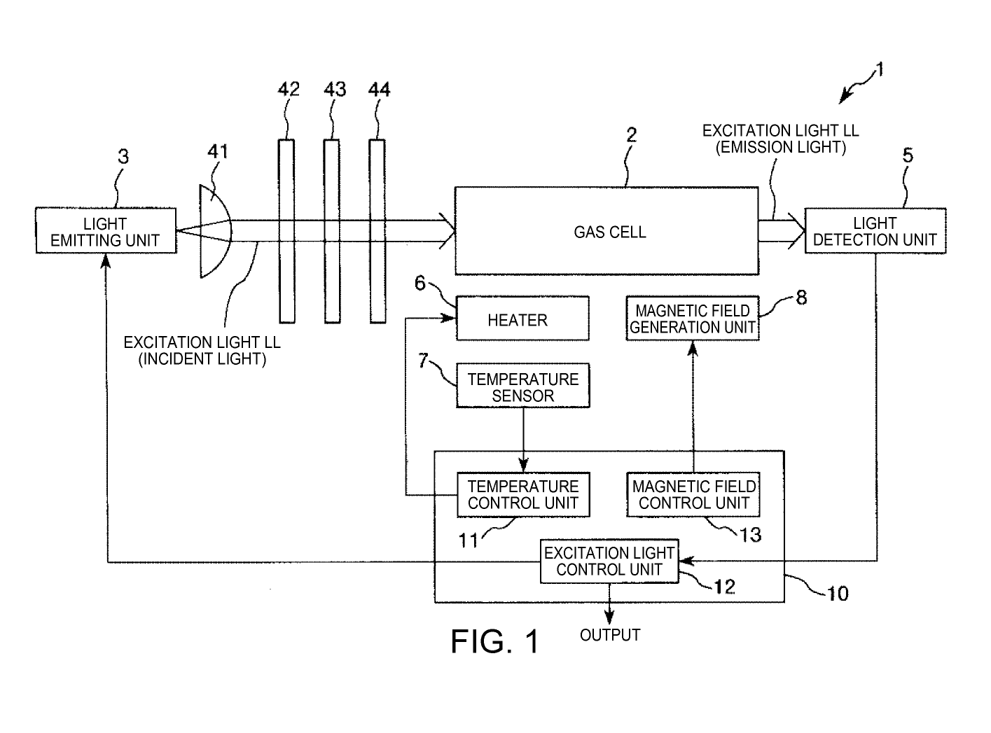

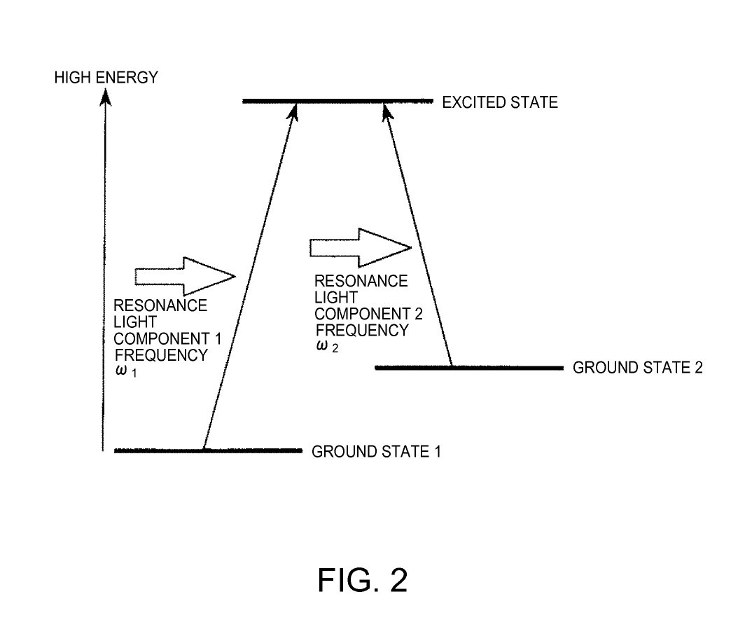

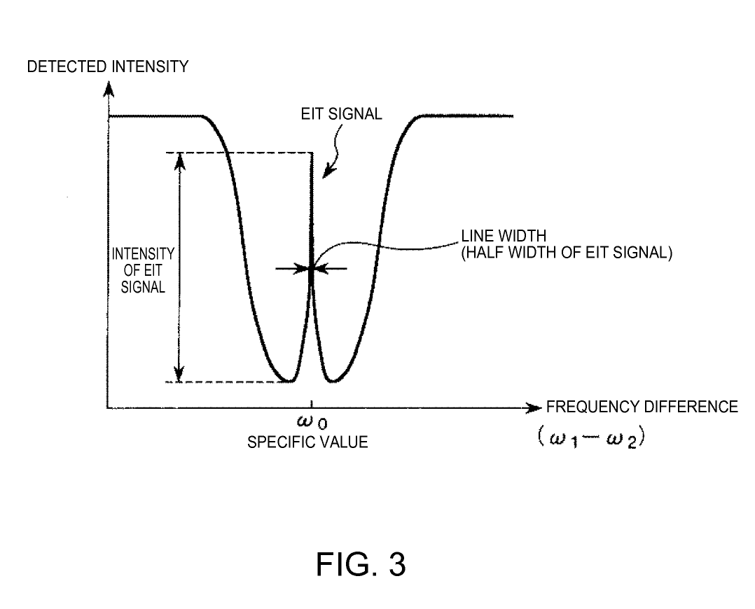

FIG. 1 is a schematic diagram illustrating an atomic oscillator (quantum interference device) according to a first embodiment of the invention. FIG. 2 is a diagram illustrating the energy state of alkali metal. FIG. 3 is a graph illustrating the relationship between a frequency difference between two light components emitted from a light emitting unit and the intensity of light detected by a light detection unit.

An atomic oscillator 1 illustrated in FIG. 1 is an atomic oscillator using a quantum interference effect. As illustrated in FIG. 1, the atomic oscillator 1 includes a gas cell 2 (atom cell), a light emitting unit 3, optical components 41, 42, 43, and 44, a light detection unit 5, a heater 6, a temperature sensor 7, a magnetic field generation unit 8, and a control unit 10.

First, the principle of the atomic oscillator 1 will be described in brief.

As illustrated in FIG. 1, in the atomic oscillator 1, the light emitting unit 3 emits excitation light LL to the gas cell 2. The excitation light LL is transmitted through the gas cell 2 and is then detected by the light detection unit 5.

A gaseous alkali metal (metal atom) is enclosed in the gas cell 2. As illustrated in FIG. 2, the alkali metal has an energy level in a three-level system and can have three states, that is, two ground states (ground states 1 and 2) with different energy levels and an excited state. In ground state 1, the energy level is lower than that in ground state 2.

The excitation light LL emitted from the light emitting unit 3 includes two kinds of resonance light components 1 and 2 with different frequencies. When the two types of resonance light components 1 and 2 are emitted to the gaseous alkali metal, the light absorption rate (light transmittance) of resonance light components 1 and 2 in the alkali metal changes depending on a difference (ω₁−ω₂) between the frequency ω₁ of resonance light component 1 and the frequency ω₂ of resonance light component 2.

When the difference (ω₁−ω₂) between the frequency ω₁ of resonance light component 1 and the frequency ω₂ of resonance light component 2 is equal to a frequency corresponding to the energy difference between ground state 1 and ground state 2, excitation from ground states 1 and 2 to the excited state is stopped. In this case, resonance light components 1 and 2 are transmitted through the alkali metal, without being absorbed by the alkali metal. This phenomenon is called a CPT phenomenon or an electromagnetically induced transparency (EIT) phenomenon.

For example, the light emitting unit 3 fixes the frequency ω₁ of resonance light component 1 and changes the frequency ω₂ of resonance light component 2. In this case, when the difference (ω₁−ω₂) between the frequency ω₁ of resonance light component 1 and the frequency ω₂ of resonance light component 2 is equal to a frequency ω₀ corresponding to the energy difference between ground state 1 and ground state 2, the detection intensity of the light detection unit 5 suddenly increases, as illustrated in FIG. 3. The light detection unit 5 detects the signal which suddenly increases as an EIT signal. The EIT signal has an eigenvalue which is determined by the type of alkali metal. Therefore, it is possible to form an oscillator using the EIT signal.

Hereinafter, each unit of the atomic oscillator 1 will be sequentially described in detail.

### Gas Cell

A gaseous alkali metal, such as rubidium, cesium, or sodium, is enclosed in the gas cell 2. In addition, a rare gas, such as argon or neon, and an inert gas, such as nitrogen, may be enclosed as a buffer gas in the gas cell 2 together with the alkali metal gas, if necessary.

The gas cell 2 includes a body portion having a through hole formed therein and a pair of window portions which close openings of the through hole formed in the body portion, which will be described in detail below. In this way, an internal space in which a gaseous alkali metal and a liquid-state or a solid-state alkali metal, which is a surplus, are enclosed is formed.

### Light Emitting Unit

The light emitting unit 3 (light source) has a function of emitting the excitation light LL for exciting alkali metal atoms in the gas cell 2.

Specifically, the light emitting unit 3 emits the two types of light components (resonance light component 1 and resonance light component 2) with different frequencies. Resonance light component 1 can excite (resonate) the alkali metal in the gas cell 2 from ground state 1 to the excited state. Resonance light component 2 can excite (resonate) the alkali metal in the gas cell 2 from ground state 2 to the excited state.

The light emitting unit 3 is not particularly limited as long as it can emit the above-mentioned excitation light. For example, a semiconductor laser, such as a vertical-cavity surface-emitting laser (VCSEL), can be used.

The temperature of the light emitting unit 3 is adjusted to a predetermined temperature by a temperature adjustment element (for example, a heating resistor or a Peltier element) (not illustrated).

### Optical Components

A plurality of optical components 41, 42, 43, and 44 are provided on the optical path of the excitation light LL between the light emitting unit 3 and the gas cell 2. Here, the optical component 41, the optical component 42, the optical component 43, and the optical component 44 are arranged in this order from the light emitting unit 3 to the gas cell 2.

The optical component 41 is a lens. Therefore, it is possible to emit the excitation light LL to the gas cell 2, without leakage.

The optical component 41 has a function of converting the excitation light LL into parallel light. Therefore, it is possible to reliably prevent the excitation light LL from being reflected from the inner wall of the gas cell 2 with a simple structure. It is possible to appropriately resonate the excitation light in the gas cell 2. As a result, it is possible to improve the oscillation characteristics of the atomic oscillator 1.

The optical component 42 is a polarizing plate. Therefore, it is possible to adjust the polarization of the excitation light LL emitted from the light emitting unit 3 in a predetermined direction.

The optical component 43 is a neutral density filter (ND filter). Therefore, it is possible to adjust (reduce) the intensity of the excitation light LL incident on the gas cell 2. Even when the output from the light emitting unit 3 is high, it is possible to adjust the amount of excitation light incident on the gas cell 2 to a desired value. In this embodiment, the optical component 43 adjusts the intensity of the excitation light LL which passes through the optical component 42 and is polarized in a predetermined direction.

The optical component 44 is a quarter-wavelength plate. Therefore, it is possible to convert the excitation light LL emitted from the light emitting unit 3 from linearly polarized light to circularly polarized light (right circularly polarized light or left circularly polarized light).

When linearly polarized excitation light is radiated to alkali metal atoms, with the alkali metal atoms in the gas cell 2 being Zeeman-split by the magnetic field of the magnetic field generation unit 8, the alkali metal atoms are uniformly dispersed at a plurality of levels where the alkali metal atoms are Zeeman-split by the interaction between the excitation light and the alkali metal atoms, which will be described below. As a result, the number of alkali metal atoms at a desired energy level is relatively less than the number of alkali metal atoms at other energy levels. Therefore, the number of atoms which cause a desired EIT phenomenon is reduced and the intensity of a desired EIT signal is reduced. As a result, the oscillation characteristics of the atomic oscillator 1 deteriorate.

In contrast, when circularly polarized excitation light is radiated to alkali metal atoms, with the alkali metal atoms in the gas cell 2 being Zeeman-split by the magnetic field of the magnetic field generation unit 8, the number of alkali metal atoms at a desired energy level among a plurality of levels where the alkali metal atoms are Zeeman-split by the interaction between the excitation light and the alkali metal atoms can be relatively greater than the number of alkali metal atoms at other energy levels, which will be described below. Therefore, the number of atoms which cause the desired EIT phenomenon increases and the intensity of the desired EIT signal increases. As a result, it is possible to improve the oscillation characteristics of the atomic oscillator 1.

### Light Detection Unit

The light detection unit 5 has a function of detecting the intensity of the excitation light LL (resonance light components 1 and 2) transmitted through the gas cell 2.

The light detection unit 5 is not particularly limited as long as it can detect the excitation light. For example, a photodetector (light receiving element), such as a solar cell or a photodiode, can be used.

### Heater

The heater 6 (heating unit) has a function of heating the gas cell 2 (specifically, the alkali metal in the gas cell 2). Therefore, it is possible to maintain the alkali metal in the gas cell 2 in a gas state with an appropriate concentration.

The heater 6 includes, for example, a heating resistor which is supplied with a current and generates heat. The heating resistor may be provided so as to come into contact with the gas cell 2 or it may be provided so as not to come into contact with the gas cell 2.

For example, when the heating resistor is provided so as to come into contact with the gas cell 2, the heating resistors are provided in a pair of window portions of the gas cell 2. Therefore, it is possible to prevent the occurrence of condensation in the window portions of the gas cell 2 due to the alkali metal atoms. As a result, it is possible to maintain the excellent characteristics (oscillation characteristics) of the atomic oscillator 1 for a long period of time. The heating resistor is made of a material having transparency to excitation light, for example, a transparent electrode material. The transparent electrode material is, for example, an oxide such as an indium tin oxide (ITO), an indium zinc oxide (IZO), In₃O₃, SnO₂, SnO₂ including Sb, or ZnO including Al. In addition, the heating resistor can be formed by, for example, a chemical vapor deposition method (CVD), such as a plasma CVD method or a thermal CVD method, a dry plating method, such as a vacuum deposition method, or a sol-gel method.

When the heating resistor is provided so as not to come into contact with the gas cell 2, heat may be transferred from the heating resistor to the gas cell 2 through a member made of metal or ceramics with high thermal conductivity.

The heater 6 is not limited to the above-mentioned form. For example, various types of heaters can be used as long as they can heat the gas cell 2. In addition, a Peltier element may be used to heat the gas cell 2, instead of the heater 6 or in addition to the heater 6.

### Temperature Sensor

The temperature sensor 7 detects the temperature of the heater 6 or the gas cell 2. The amount of heat generated from the heater 6 is controlled on the basis of the detection result of the temperature sensor 7. Therefore, it is possible to maintain the alkali metal atoms in the gas cell 2 at a desired temperature.

The installation position of the temperature sensor 7 is not particularly limited. For example, the temperature sensor 7 may be provided on the heater 6 or the outer surface of the gas cell 2.

The temperature sensor 7 is not particularly limited. For example, various known temperature sensors, such as a thermistor and a thermocouple, can be used.

### Magnetic Field Generation Unit

The magnetic field generation unit 8 has a function of generating the magnetic field which Zeeman-splits a plurality of energy levels where alkali metal in the gas cell 2 is degenerated. Therefore, the Zeeman splitting makes it possible to increase the gap between different energy levels at which alkali metal is degenerated and to improve the resolution. As a result, it is possible to improve the accuracy of the oscillating frequency of the atomic oscillator 1.

The magnetic field generation unit 8 is, for example, a Helmholtz coil which is provided on both sides of the gas cell 2 or a solenoid coil which is provided so as to cover the gas cell 2. Therefore, it is possible to generate a uniform magnetic field in one direction in the gas cell 2.

The magnetic field generated by the magnetic field generation unit 8 is a constant magnetic field (DC magnetic field). However, an AC magnetic field may be superimposed on the DC magnetic field.

### Control Unit

The control unit 10 has a function of controlling the light emitting unit 3, the heater 6, and the magnetic field generation unit 8.

The control unit 10 includes an excitation light control unit 12 which controls the frequencies of resonance light components 1 and 2 from the light emitting unit 3, a temperature control unit 11 which controls the temperature of the alkali metal in the gas cell 2, and a magnetic field control unit 13 which controls the magnetic field from the magnetic field generation unit 8.

The excitation light control unit 12 controls the frequencies of resonance light components 1 and 2 emitted from the light emitting unit 3 on the basis of the detection result of the light detection unit 5. Specifically, the excitation light control unit 12 controls the frequencies of resonance light components 1 and 2 emitted from the light emitting unit 3 such that the frequency difference (ω₁−ω₂) is equal to the frequency ω₀ unique to the alkali metal.

The excitation light control unit 12 includes a voltage-controlled crystal oscillator (oscillation circuit) (not illustrated) and outputs an output signal from the voltage-controlled crystal oscillator as the output signal from the atomic oscillator 1 while synchronizing and adjusting the oscillating frequency of the voltage-controlled crystal oscillator on the basis of the detection result of the light detection unit 5.

For example, the excitation light control unit 12 includes a multiplier (not illustrated) which multiplies the frequency of the output signal from the voltage-controlled crystal oscillator, superimposes a signal (high-frequency signal) which is multiplied by the multiplier on a DC bias current, and inputs the signal as a driving signal to the light emitting unit 3. Therefore, the excitation light control unit 12 controls the voltage-controlled crystal oscillator such that the light detection unit 5 detects the EIT signal. As a result, a signal with a desired frequency is output from the voltage-controlled crystal oscillator. When the desired frequency of the output signal from the atomic oscillator 1 is f, the multiplication rate of the multiplier, for example, is ω₀/(2×f). Therefore, when the oscillating frequency of the voltage-controlled crystal oscillator is f, it is possible to modulate light emitted from a light emitting element, such as a semiconductor laser, included in the light emitting unit 3 using the signal from the multiplier and to emit two light components having a frequency difference (ω₁−ω₂) of ω₀ therebetween.

The temperature control unit 11 controls the supply of a current to the heater 6 on the basis of the detection result of the temperature sensor 7. Therefore, it is possible to maintain the gas cell 2 in a desired temperature range. For example, the temperature of the gas cell 2 is adjusted to about 70° C. by the heater 6.

The magnetic field control unit 13 controls the supply of a current to the magnetic field generation unit 8 such that the magnetic field generation unit 8 generates a constant magnetic field.

The control unit 10 is provided in, for example, an IC chip mounted on a substrate.

The structure of the atomic oscillator 1 has been described in brief above.

### Detailed Description of Gas Cell

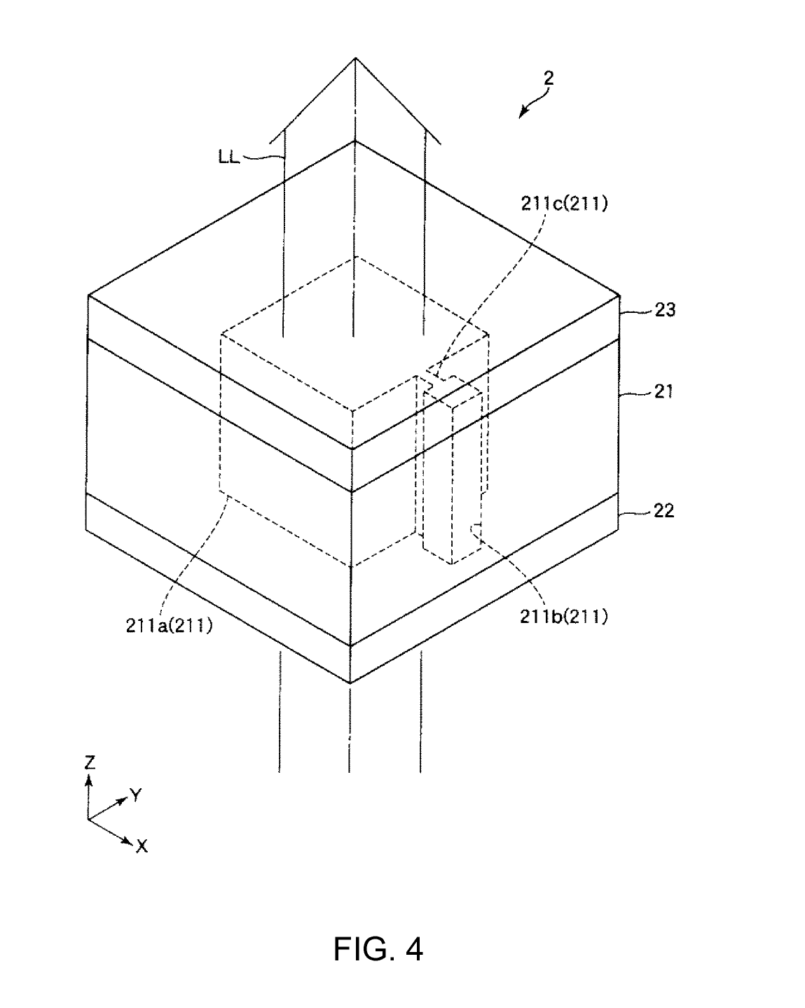

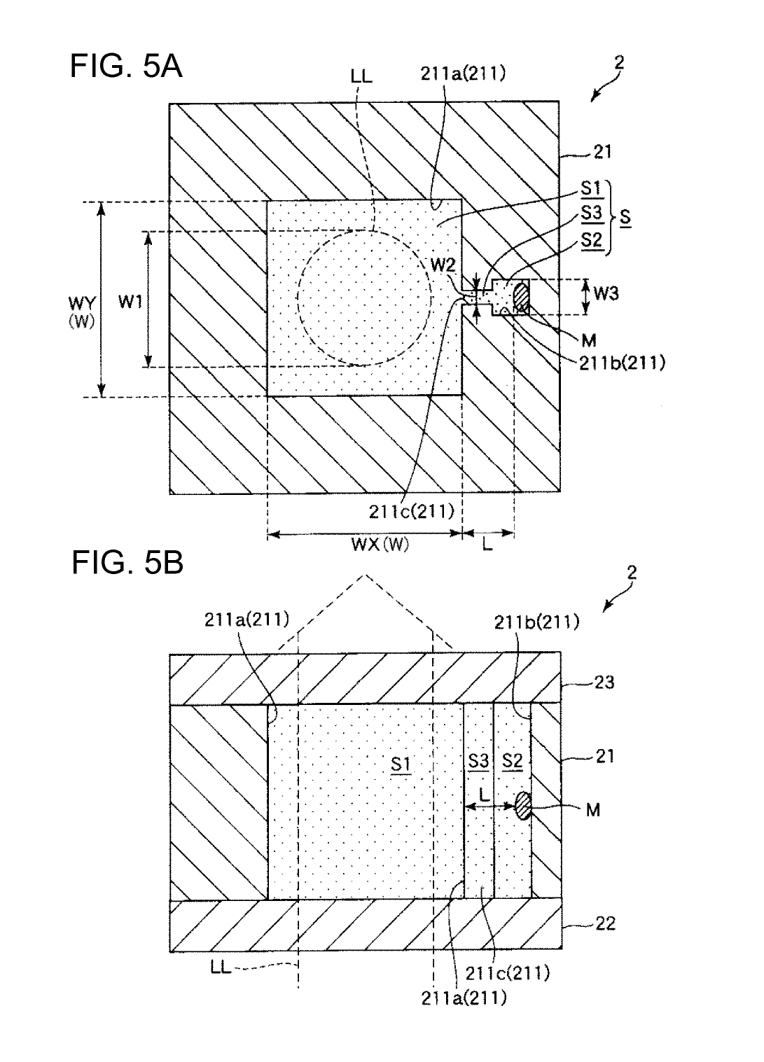

FIG. 4 is a perspective view illustrating the atom cell included in the atomic oscillator illustrated in FIG. 1. FIG. 5A is a horizontal cross-sectional view illustrating the atom cell illustrated in FIG. 4 and FIG. 5B is a vertical cross-sectional view illustrating the atom cell illustrated in FIG. 4.

In FIG. 4, for convenience of explanation, the X-axis, the Y-axis, and the Z-axis are illustrated as three axes which are perpendicular to each other. The leading end side of each arrow illustrated in FIG. 4 is referred to as a “positive (+) side” and the base end side thereof is referred to as a “negative (−) side”. In the following description, for convenience of explanation, a direction parallel to the X-axis is referred to as an “X-axis direction”, a direction parallel to the Y-axis is referred to as a “Y-axis direction”, and a direction parallel to the Z-axis is referred to as a “Z-axis direction”. In addition, a +Z-axis direction is referred to an “upper direction” and a −Z-axis direction is referred to as a “lower direction”.

As illustrated in FIG. 4 and FIGS. 5A and 5B, the gas cell 2 includes a body portion 21 and a pair of window portions 22 and 23 which are provided so as to have a body portion 21 interposed therebetween.

A through hole 211 is formed in the body portion 21 so as to pass through the body portion 21 in the Z-axis direction. The through hole 211 includes through holes 211a and 211b and a through hole 211c which connects the through holes 211a and 211b.

The material forming the body portion 21 is not particularly limited. For example, the body portion 21 is made of a glass material, a crystal, a metal material, a resin material, or a silicon material. Among them, it is preferable to use any one of the glass material, the crystal, and the silicon material. It is more preferable to use the silicon material. Therefore, even when a small gas cell 2 with a width or height of 10 mm or less is formed, it is possible to easily form the body portion 21 with high accuracy using a microfabrication technique such as etching. That is, it is possible to form spaces S1, S2, and S3 with high accuracy using a MEMS processing technique and to reduce the size of the gas cell 2.

An end surface (lower end surface) of the body portion 21 in the −Z-axis direction is bonded to the window portion 22 and an end surface (upper end surface) of the body portion 21 in the +Z-axis direction is bonded to the window portion 23. Therefore, both end openings of the through hole 211 are closed and an internal space S including the space S1 formed by the through hole 211a, the space S2 formed by the through hole 211b, and the space S3 formed by the through hole 211c is formed. An alkali metal is accommodated in the internal space S. Here, the body portion 21 and the pair of window portions 22 and 23 are referred to as a “wall portion” forming the internal space S in which the alkali metal is enclosed.

A method for bonding the body portion 21 and the window portions 22 and 23 is determined by these constituent materials and is not particularly limited as long as it can airtightly bond the body portion 21 and the window portions 22 and 23. For example, it is possible to use a bonding method with an adhesive, a direct bonding method, and an anodic bonding method. However, it is preferable to use a heating and bonding method such as the direct bonding method or the anodic bonding method. Therefore, it is possible to airtightly bond the body portion 21 and the window portions 22 and 23 with a relatively simple structure.

A gaseous alkali metal is mainly accommodated in the space S1. The gaseous alkali metal accommodated in the space S1 is excited by the excitation light LL. That is, the space S1 forms a “light passage portion (light passage space)” through which the excitation light LL passes. In this embodiment, the cross section of the space S1 has a rectangular shape. However, the cross section of a region through which the excitation light LL actually passes has a circular shape and is slightly smaller than that of the space S1. The shape of the cross section of the space S1 is not limited to the rectangular shape, but may be, for example, other polygons, such as a pentagon, a circle, or an ellipse.

The space S2 is a “metal reservoir portion” in which a liquid-state or a solid-state alkali metal M is accommodated. The space S2 is connected to the space S1 through the space S3. Therefore, when the gaseous alkali metal in the space S1 is insufficient, the alkali metal M is gasified and is excited by the excitation light LL. As viewed from the Z-axis direction (a direction in which the pair of window portions 22 and 23 overlap each other (arranged in a line)) (hereinafter, referred to as a “plan view”), the width W3 (length in the Y-axis direction) of the space S2 is smaller than the widths WX (length in the X-axis direction) and WY (length in the Y-axis direction) of the space S1. Therefore, it is possible to reduce the size of the gas cell 2.

As described above, the spaces S1, S2, and S3 are formed such that both end openings of the through hole 211 formed in the body portion 21 are closed by the pair of window portions 22 and 23. Therefore, it is possible to simply form a small gas cell 2 including the spaces S1, S2, and S3 with high accuracy. Specifically, for example, when a substrate, such as a silicon substrate or a glass substrate, is processed by a microfabrication technique, such as etching, it is possible to easily and effectively form a small body portion 21 with high accuracy. Therefore, it is possible to simply form a small gas cell 2 with high accuracy. In particular, anatomic oscillator using CPT has a smaller size than an atomic oscillator using a double resonance phenomenon. In recent years, the atomic oscillator using CPT has been expected to be incorporated into various apparatuses and there has been a strong demand for a reduction in the size of the gas cell. Therefore, the effect of simply forming a small gas cell 2 with high accuracy is important in the atomic oscillator 1 using CPT.

Specifically, the width W3 of the space S2 is determined by the volume of surplus alkali metal M or the entire volume of the gas cell 2 and is not particularly limited. However, the width W3 is preferably equal to or greater than 0.1 mm and equal to or less than 2 mm and more preferably equal to or greater than 0.1 mm and equal to or less than 1 mm.

In this embodiment, as illustrated in FIG. 5A, the space S2 has a rectangular shape as viewed from the Z-axis direction. The shape of the cross section of the space S2 is not limited to the rectangular shape, but may be, for example, other polygons, such as a pentagon, a circle, or an ellipse.

The space S3 which is a “connection portion” connecting the space S1 and the space S2 has a shape which extends in a straight line, as viewed from the Z-axis direction. As viewed from the Z-axis direction (a direction in which the pair of window portions 22 and 23 overlap each other), the width W2 (length in the Y-axis direction) of the space S3 is smaller than the width W3 (length in the Y-axis direction) of the space S2.

The window portions 22 and 23 bonded to the body portion 21 each have transparency to the excitation light emitted from the light emitting unit 3. The window portion is an incident-side window portion through which the excitation light LL is incident on the space S1 of the gas cell 2 and the window portion 23 is an emission-side window portion through which the excitation light LL is emitted from the space S1 of the gas cell 2.

The window portions 22 and 23 each have a plate shape.

The material forming the window portions 22 and 23 is not particularly limited as long as it has transparency to the excitation light. For example, the window portions 22 and 23 are made of a glass material or a crystal. When the window portions 22 and 23 are made of the glass material, it is possible to simply and airtightly bond the body portion 21 made of a silicon material to the window portions 22 and 23 using the anodic bonding method. In addition, the window portions 22 and 23 may be made of silicon, according to the thickness of the window portions 22 and 23 and the intensity of the excitation light.

In the gas cell 2 having the above-mentioned structure, the space S3 (connection portion) which connects the space S1 (light passage portion) and the space S2 (metal reservoir portion) has a portion with the width W2 less than the width W3 of the space S2. Therefore, it is possible to reduce the movement of the liquid-state alkali metal M in the space S2 to the space S1 while ensuring the size of the space S2 capable of accommodating the necessary liquid-state alkali metal M and to reduce the influence of the liquid-state alkali metal M on the gaseous alkali metal in the space S1. As a result, it is possible to suppress deterioration of the characteristics of the surplus alkali metal.

In this embodiment, as described above, the space S3 has a portion with a width less than the width W3 of the space S2, as viewed from the direction in which the pair of window portions 22 and 23 overlap each other. The space S2 is formed in the entire region between the pair of window portions 22 and 23. Therefore, the symmetry of the spectrum shape of the resonance signal is improved, which makes it possible to improve the stability of the frequency. In addition, it is possible to form the body portion 21 including the space S3 with a smaller width than the space S2, using a simple method which forms the through hole 211 in the substrate so as to pass through the substrate in the thickness direction.

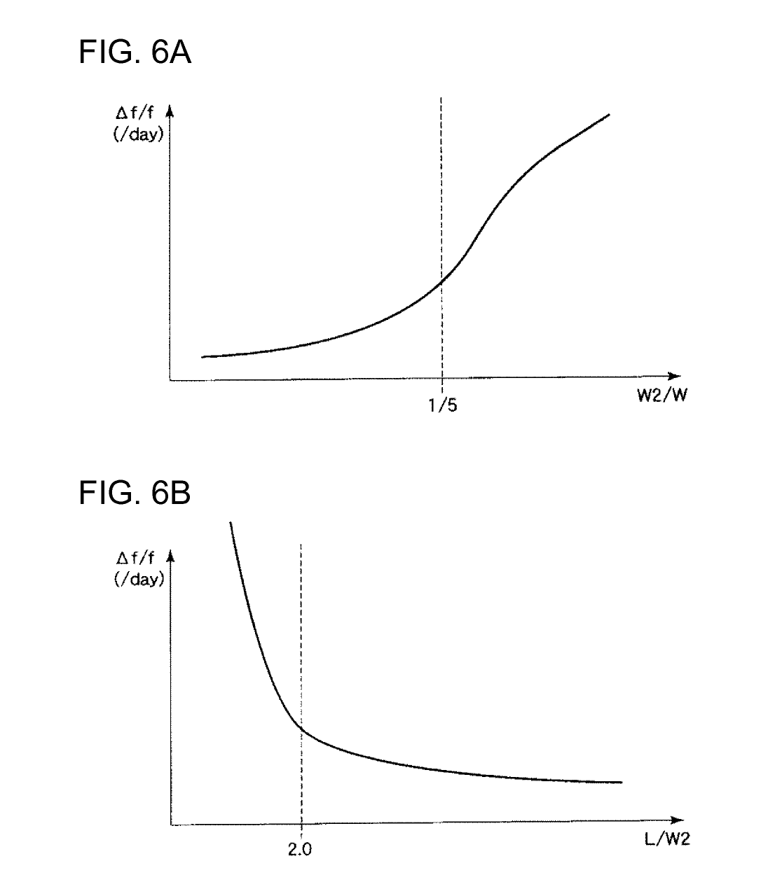

FIG. 6A is a graph illustrating the relationship between the stability of the frequency and the ratio (W2/W) of the width W2 of the connection portion to the width W of the light passage portion and FIG. 6B is a graph illustrating the stability of the frequency and the ratio (L/W2) of a distance L between the light passage portion and the metal reservoir portion along the connection portion to the width W2 of the connection portion.

The inventors prepared a plurality of gas cells in which the widths WX and WY of the space S1 were 2 mm and the spaces S3 had different widths W2, measured the stability of the frequency of atomic oscillators using the gas cells per day, and obtained the results illustrated in FIG. 6A for the relationship between the stability of the frequency and the ratio (W2/W) of the width W2 of the space S3 to the width W of the space S1. Here, the relationship between the ratio (W2/W) and the stability of the frequency can be considered to be substantially identical to the relationship between the stability of the frequency and the ratio (W2/W1) of the width W2 of the space S1 to the width W1 of a region through which excitation light actually passes. Even when the widths WX and WY of the space S1 are different from the above-mentioned values, the same measurement as described above was performed and the measurement result had the same tendency as the result illustrated in FIG. 6A. As the widths WX and WY of the space S1 were reduced, the tendency became remarkable. That is, as the space S1 is reduced, the influence of the liquid-state alkali metal increases.

From the results illustrated in FIG. 6A, the ratio W2/W is preferably equal to or less than 1/5, more preferably equal to or less than 1/6, and most preferably equal to or less than 1/7. When the space S3 has a portion with the width W2 in the above-mentioned range, it is possible to effectively reduce the influence of the liquid-state alkali metal M in the space S2 on the gaseous alkali metal in the space S1.

Specifically, the width W2 is preferably equal to or greater than 0.1 μm and equal to or less than 400 μm, more preferably equal to or greater than 1 μm and equal to or less than 300 μm, and most preferably equal to or greater than 10 μm and equal to or less than 200 μm. Therefore, even when the space S1 is small, it is possible to effectively reduce the influence of the liquid-state alkali metal M in the space S2 on the gaseous alkali metal in the space S1. In contrast, when the width W2 is too large, it is difficult to reduce the size of the gas cell 2. On the other hand, when the width W2 is too small, it is difficult to perform processing when the gas cell 2 is manufactured.

In addition, the inventors prepared a plurality of gas cells in which the widths WX and WY of the space S1 were 2 mm and the width W2 of the space S3 was 100 μm, and the space S3 had different lengths, measured the stability of the frequency of atomic oscillators using the gas cells per day, and obtained the results illustrated in FIG. 6B for the relationship between the stability of the frequency and the ratio (L/W2) of the distance L between the space S1 and the space S2 along the space S3 to the width W2 of the space S3. Here, strictly, the distance L is the distance between the space S1 and the alkali metal M in the space S2 along the space S3. Even when the widths WX and WY of the space S1 were different from the above-mentioned values, the same measurement as described above was performed and the measurement result had the same tendency as the result illustrated in FIG. 6B. As the widths WX and WY of the space S1 were reduced, the tendency became remarkable. That is, as the space S1 is reduced, the influence of liquid-state alkali metal increases.

From the result illustrated in FIG. 6B, the distance L is preferably greater than the width W2 of the space S3, more preferably equal to or greater than two times the width W2 of the space S3, and most preferably equal to or greater than three times the width W2 of the space S3. In this case, it is possible to effectively reduce the influence of the liquid-state alkali metal M in the space S3 on the gaseous alkali metal in the space S1.

Specifically, the distance L is preferably equal to or greater than 200 μm and equal to or less than 3 mm, more preferably equal to or greater than 200 μm and equal to or less than 1 mm, and most preferably equal to or greater than 300 μm and equal to or less than 800 μm. In this case, it is possible to effectively reduce the influence of the liquid-state alkali metal M in the space S2 on the gaseous alkali metal in the space S1, while reducing the size of the gas cell 2.

### Second Embodiment

Next, a second embodiment of the invention will be described.

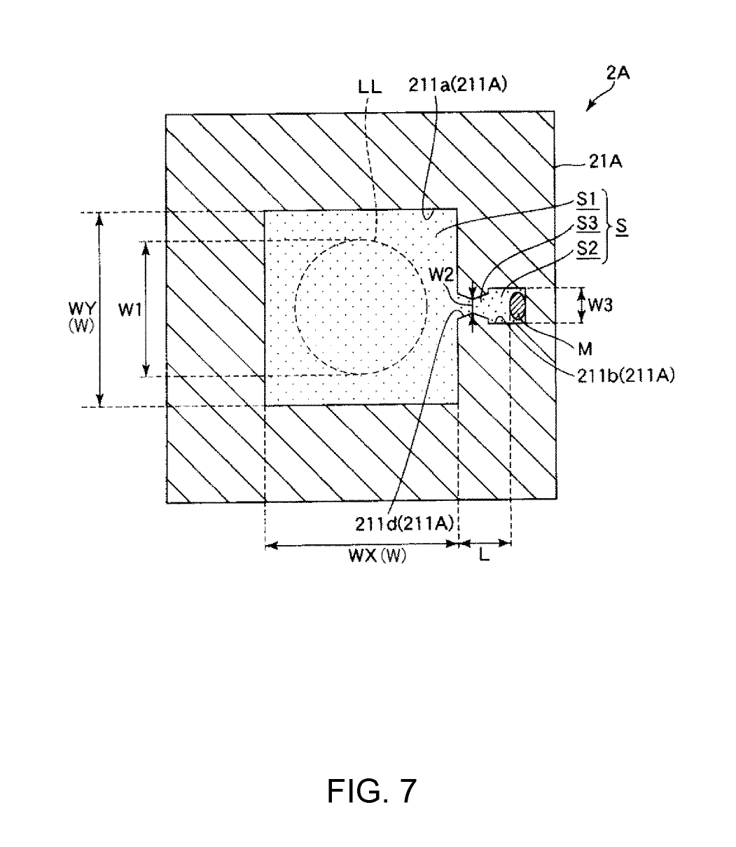

FIG. 7 is a horizontal cross-sectional view illustrating an atom cell according to the second embodiment of the invention.

This embodiment is the same as the first embodiment except for the shape of a connection portion.

In the second embodiment, the description is focused on the difference from the above-described embodiment and the description of the same components as those in the above-described embodiment will not be repeated.

A gas cell 2A (atom cell) illustrated in FIG. 7 includes a body portion 21A, instead of the body portion 21 according to the first embodiment.

A through hole 211A is formed in the body portion 21A so as to pass through the body portion 21A in the Z-axis direction. The through hole 211A includes through holes 211a and 211b and a through hole 211d which connects the through holes 211a and 211b. Both end openings of the through hole 211A are closed by a pair of window portions 22 and 23 and an internal space S including a space S1 formed by the through hole 211a, a space S2 formed by the through hole 211b, and a space S3 formed by the through hole 211d is formed.

The space S3 according to this embodiment includes a portion with a width that increases from an intermediate portion to the space S1 and a portion with a width that increases from the intermediate portion to the space S2. The width W2, which is the minimum width of the space S3, has the relationship described in the first embodiment.

According to the above-described second embodiment, it is possible to suppress deterioration of characteristics due to surplus alkali metal M.

### Third Embodiment

Next, a third embodiment of the invention will be described.

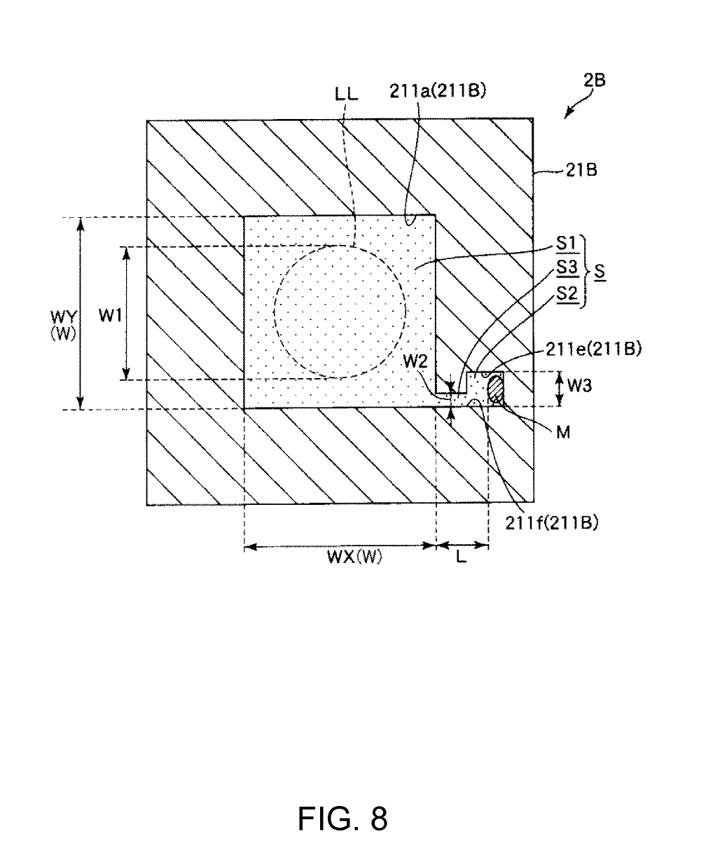

FIG. 8 is a horizontal cross-sectional view illustrating an atom cell according to the third embodiment of the invention.

This embodiment is the same as the first embodiment except for the arrangement of a metal reservoir portion and a connection portion.

In the third embodiment, the description is focused on the difference from the above-described embodiments and the description of the same components as those in the above-described embodiments will not be repeated.

A gas cell 2B (atom cell) illustrated in FIG. 8 includes a body portion 21B, instead of the body portion 21 according to the first embodiment.

A through hole 211B is formed in the body portion 21B so as to pass through the body portion 21B in the Z-axis direction. The through hole 211B includes through holes 211a and 211e and a through hole 211f which connects the through holes 211a and 211e. Both end openings of the through hole 211B are closed by a pair of window portions 22 and 23 and an internal space S including a space S1 formed by the through hole 211a, a space S2 formed by the through hole 211e, and a space S3 formed by the through hole 211f is formed.

The space S3 according to this embodiment is formed at the corner of the space S1 which has a rectangular shape in a plan view. Therefore, it is possible to further reduce the influence of liquid-state alkali metal M in the space S2 on a region through which excitation light LL actually passes.

According to the above-described third embodiment, it is possible to suppress deterioration of characteristics due to surplus alkali metal M.

### Fourth Embodiment

Next, a fourth embodiment of the invention will be described.

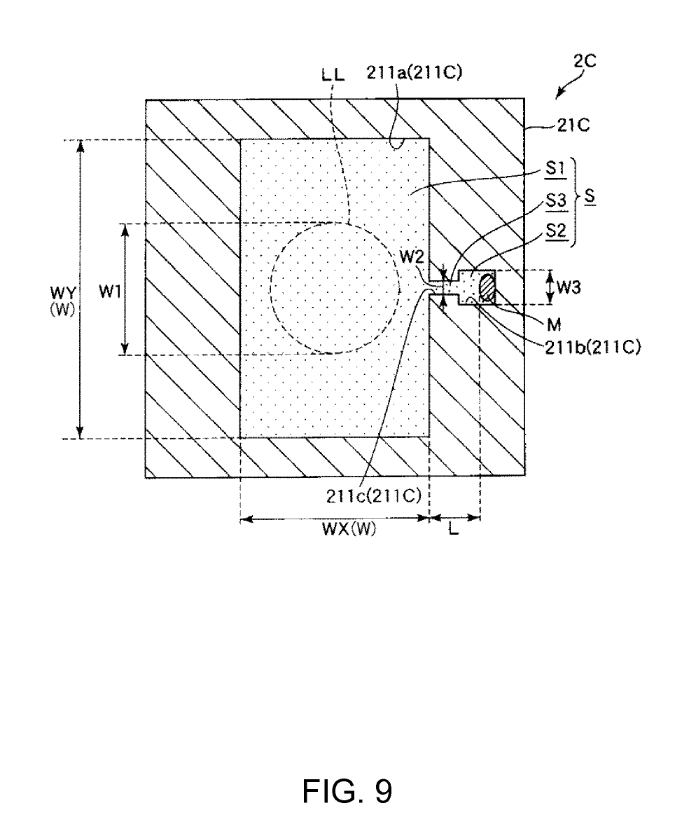

FIG. 9 is a horizontal cross-sectional view illustrating an atom cell according to the fourth embodiment of the invention.

This embodiment is the same as the first embodiment except for the shape of a light passage portion.

In the fourth embodiment, the description is focused on the difference from the above-described embodiments and the description of the same components as those in the above-described embodiments will not be repeated.

A gas cell 2C (atom cell) illustrated in FIG. 9 includes a body portion 21C, instead of the body portion 21 according to the first embodiment.

A through hole 211C is formed in the body portion 21C so as to pass through the body portion 21C in the Z-axis direction. The through hole 211C includes through holes 211g and 211b and a through hole 211c which connects the through holes 211g and 211b. Both end openings of the through hole 211C are closed by a pair of window portions 22 and 23 and an internal space S including a space S1 formed by the through hole 211g, a space S2 formed by the through hole 211b, and a space S3 formed by the through hole 211c is formed.

The space S1 according to this embodiment has a rectangular shape having a direction in which the space S1 and the space S2 are arranged in a line as a short-side direction in a plan view. The width WY of the space S1 in the short-side direction is the width W and has the relationship described in the first embodiment.

According to the above-described fourth embodiment, it is possible to suppress deterioration of characteristics due to surplus alkali metal M.

### Fifth Embodiment

Next, a fifth embodiment of the invention will be described.

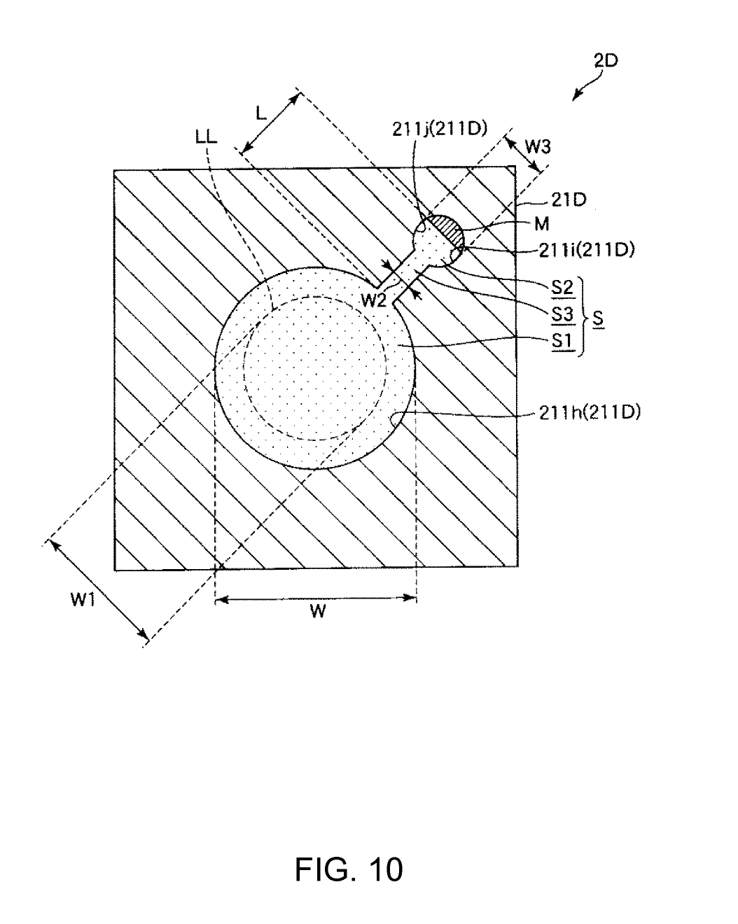

FIG. 10 is a horizontal cross-sectional view illustrating an atom cell according to the fifth embodiment of the invention.

This embodiment is the same as the first embodiment except for the shape and arrangement of a light passage portion, a metal reservoir portion, and a connection portion.

In the fifth embodiment, the description is focused on the difference from the above-described embodiments and the description of the same components as those in the above-described embodiments will not be repeated.

A gas cell 2D (atom cell) illustrated in FIG. 10 includes a body portion 21D, instead of the body portion 21 according to the first embodiment.

A through hole 211D is formed in the body portion 21D so as to pass through the body portion 21D in the Z-axis direction. The through hole 211D includes cylindrical through holes 211h and 211i and a slit-shaped through hole 211j which connects the through holes 211h and 211i. Both end openings of the through hole 211D are closed by a pair of window portions 22 and 23 and an internal space S including a space S1 formed by the through hole 211h, a space S2 formed by the through hole 211i, and a space S3 formed by the through hole 211j is formed.

According to the above-described fifth embodiment, it is possible to suppress deterioration of characteristics due to surplus alkali metal M.

### Sixth Embodiment

Next, a sixth embodiment of the invention will be described.

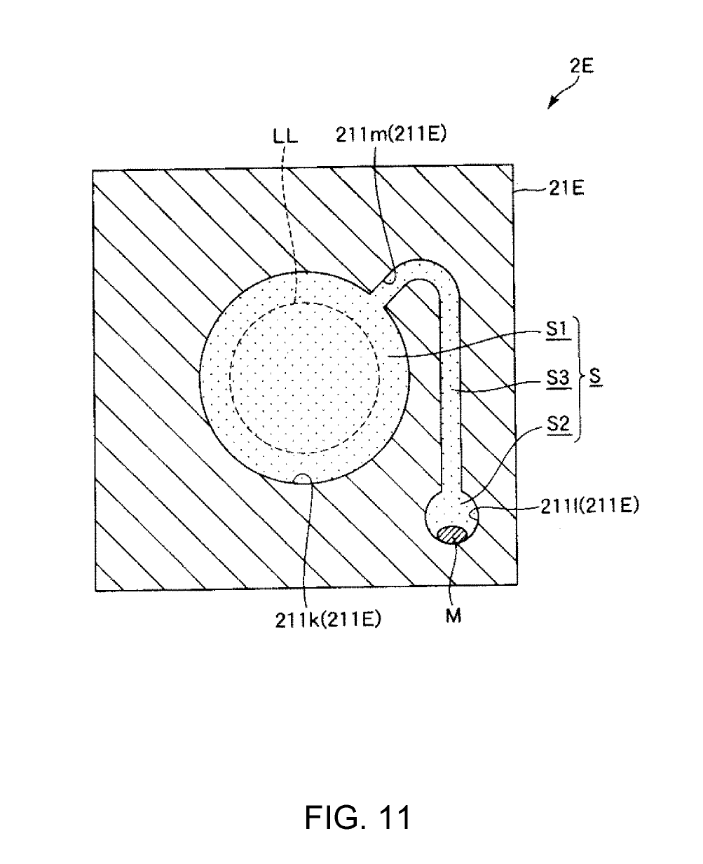

FIG. 11 is a horizontal cross-sectional view illustrating an atom cell according to the sixth embodiment of the invention.

This embodiment is the same as the first embodiment except for the arrangement of a metal reservoir portion and a connection portion. In addition, this embodiment is the same as the fifth embodiment except for the structure of the connection portion.

In the sixth embodiment, the description is focused on the difference from the above-described embodiments and the description of the same components as those in the above-described embodiments will not be repeated.

A gas cell 2E (atom cell) illustrated in FIG. 11 includes a body portion 21E, instead of the body portion 21 according to the first embodiment.

A through hole 211E is formed in the body portion 21E so as to pass through the body portion 21E in the Z-axis direction. The through hole 211E includes cylindrical through holes 211k and 211l and a slit-shaped through hole 211m which connects the through holes 211k and 211l. Both end openings of the through hole 211E are closed by a pair of window portions 22 and 23 and an internal space S including a space S1 formed by the through hole 211k, a space S2 formed by the through hole 211l, and a space S3 formed by the through hole 211m is formed.

The space S3 according to this embodiment has a curved or bent portion in a plan view. Therefore, it is possible to increase the length of the space S3 while reducing the size of the gas cell 2E. The curved or bent portion of the space S3 can limit the movement of alkali metal from the space S2 to the space S1. Therefore, it is possible to further reduce the influence of liquid-state alkali metal Min the space S2 on a region through which excitation light LL actually passes.

According to the above-described sixth embodiment, it is possible to suppress deterioration of characteristics due to surplus alkali metal M.

### Seventh Embodiment

Next, a seventh embodiment of the invention will be described.

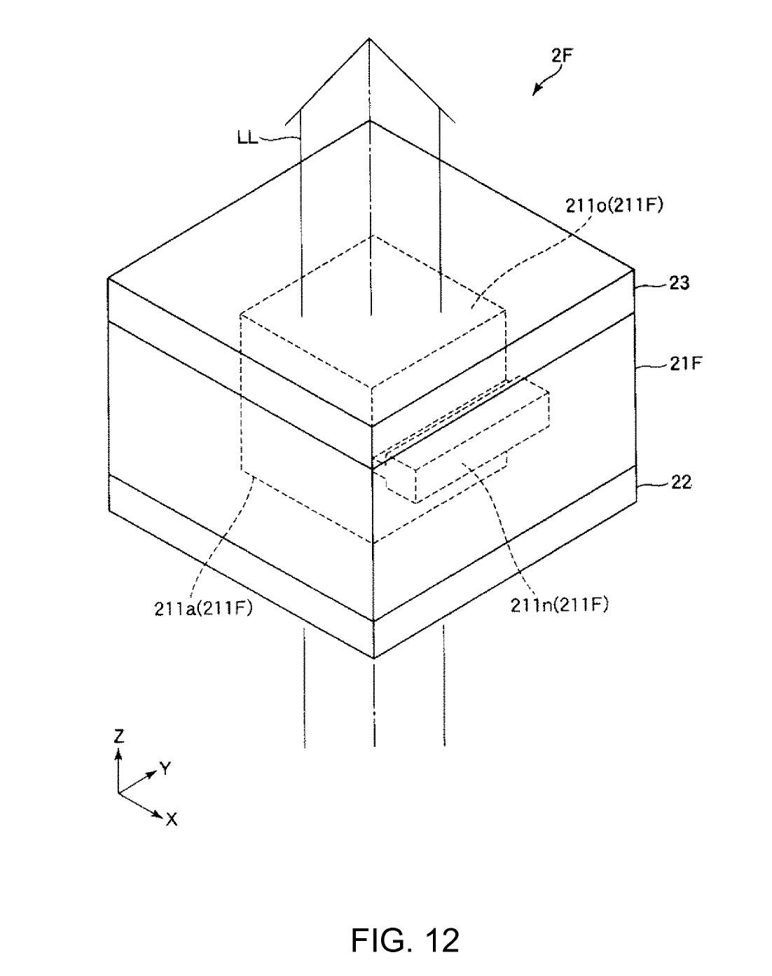

FIG. 12 is a perspective view illustrating an atom cell according to the seventh embodiment of the invention.

This embodiment is the same as the first embodiment except for the arrangement of a metal reservoir portion and a connection portion.

In the seventh embodiment, the description is focused on the difference from the above-described embodiments and the description of the same components as those in the above-described embodiments will not be repeated.

A gas cell 2F (atom cell) illustrated in FIG. 12 includes a body portion 21F, instead of the body portion 21 according to the first embodiment.

A through hole 211F is formed in the body portion 21F so as to pass through the body portion 21F in the Z-axis direction. The through hole 211F includes a through hole 211a and through holes 211n and 211so which are provided in the middle of the through hole 211F in the thickness direction. Both end openings of the through hole 211F are closed by a pair of window portions 22 and 23 and an internal space S including a space S1 formed by the through hole 211a, a space S2 formed by the through hole 211n, and a space S3 formed by the through hole 211o is formed.

The spaces S2 and S3 according to this embodiment each extend in a direction perpendicular to the direction in which the pair of window portions 22 and 23 overlap each other. The space S3 has a portion with a smaller width than the space S2, as viewed from the direction perpendicular to the direction in which the pair of window portions 22 and 23 overlap each other. According to this structure, it is possible to increase the distance between an opening of the space S3 close to the space S1 and the pair of window portions 22 and 23. Therefore, it is possible to effectively reduce the movement of liquid-state alkali metal in the space S2 to the window portions 22 and 23. As a result, it is possible to effectively suppress deterioration of characteristics due to surplus alkali metal.

According to the above-described seventh embodiment, it is possible to suppress deterioration of characteristics due to surplus alkali metal M.

### 2. Electronic Apparatus

The above-mentioned atomic oscillator can be incorporated into various electronic apparatuses. These electronic apparatuses are highly reliable.

Hereinafter, the electronic apparatus according to the invention will be described.

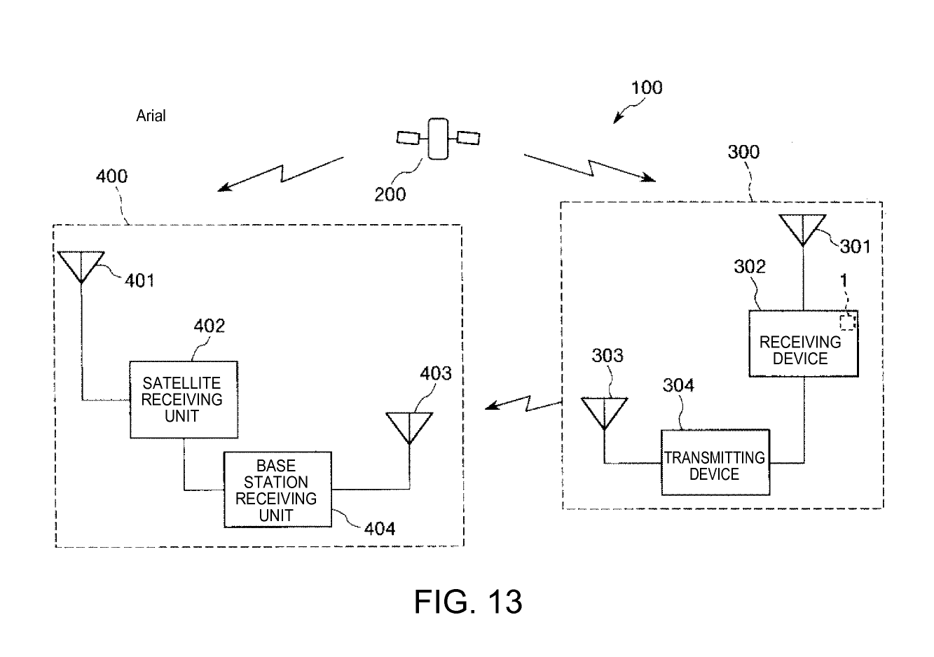

FIG. 13 is a diagram illustrating a schematic structure when the atomic oscillator according to the invention is used in a positioning system using a GPS satellite.

A positioning system 100 illustrated in FIG. 13 includes a GPS satellite 200, a base station apparatus 300, and a GPS receiving apparatus 400.

The GPS satellite 200 transmits positioning information (GPS signal).

The base station apparatus 300 includes, for example, a receiving device 302 that receives positioning information from the GPS satellite 200 with high accuracy through an antenna 301 provided at an electronic reference point (GPS continuous observation station) and a transmitting device 304 that transmits the positioning information received by the receiving device 302 through an antenna 303.

Here, the receiving device 302 is an electronic device including the above-mentioned atomic oscillator 1 according to the invention as a reference frequency oscillation source. The receiving device 302 is highly reliable. In addition, the positioning information received by the receiving device 302 is transmitted in real time by the transmitting device 304.

The GPS receiving apparatus 400 includes a satellite receiving unit 402 that receives the positioning information from the GPS satellite 200 through an antenna 401 and a base station receiving unit 404 that receives the positioning information from the base station apparatus 300 through an antenna 403.

3. Moving object

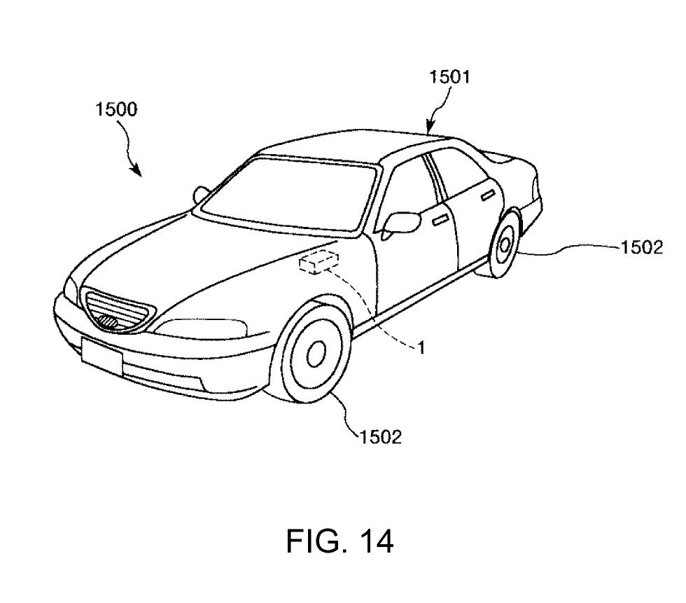

FIG. 14 is a diagram illustrating an example of a moving object according to the invention.

In FIG. 14, a moving object 1500 includes a vehicle body 1501 and four wheels 1502 and is configured such that the wheels 1502 are rotated by a power source (engine) (not illustrated) provided in the vehicle body 1501. The atomic oscillator 1 is provided in the moving object 1500.

According to the moving object, it is possible to exhibit a high level of reliability.

The electronic apparatus according to the invention is not limited to the above and can be applied to, for example, mobile phones, digital still cameras, ink jet discharge apparatuses (for example, ink jet printers), personal computers (mobile personal computers and laptop personal computers), televisions, video cameras, video tape recorders, car navigation apparatuses, pagers, electronic organizers (including electronic organizers with a communication function), electronic dictionaries, electronic calculators, electronic game machines, word processors, work stations, videophones, security television monitors, electronic binoculars, POS terminals, medical apparatuses (for example, electronic thermometers, blood pressure manometers, blood glucose meters, electrocardiogram measurement apparatuses, medical ultrasound equipment, and electronic endoscopes), fish finders, measurement instruments, meters (for example, meters of vehicles, airplanes, and ships), flight simulators, digital terrestrial broadcast systems, and mobile base stations.

The atom cell, the quantum interference device, the atomic oscillator, the electronic apparatus, and the moving object according to the invention have been described above with reference to the embodiments illustrated in the drawings. However, the invention is not limited thereto.

The configuration of each unit according to the invention can be replaced with an arbitrary configuration that has the same functions as those in the above-described embodiments. In addition, arbitrary configurations can be added.

In the invention, arbitrary configurations according to the above-described embodiments may be combined with each other.

In the above-described embodiments, an example in which the atom cell according to the invention is applied to the quantum interference device that performs the resonance transition of, for example, cesium using the quantum interference effect of two types of light components with different wavelengths has been described above. However, the application of the atom cell according to the invention is not limited thereto. For example, the atom cell according to the invention can also be used in a double resonance device which performs the resonance transition of, for example, rubidium using the double resonance phenomenon caused by light and microwaves.

The entire disclosure of Japanese Patent Application No. 2014-058506, filed Mar. 20, 2014 is expressly incorporated by reference herein.

What is claimed is:

1. An atom cell comprising:
metal;
a light passage portion in which the metal in a gas state is enclosed;
a metal reservoir portion in which the metal in a liquid state or a solid state is arranged; and
a connection portion that connects the light passage portion and the metal reservoir portion and has a part with a smaller width than the metal reservoir portion.

2. The atom cell according to claim 1, further comprising:
a pair of window portions; and
a body portion that is provided between the pair of window portions, forms the light passage portion together with the pair of window portions, and includes the metal reservoir portion and the connection portion.

3. The atom cell according to claim 2,
wherein the connection portion has a part with a smaller width than the metal reservoir portion, as viewed from a direction in which the pair of window portions overlap each other.

4. The atom cell according to claim 2,
wherein the connection portion has a part with a width that is equal to or less than one-fifth of the width of the light passage portion, as viewed from a direction in which the pair of window portions overlap each other.

5. The atom cell according to claim 2,
wherein the connection portion has a part with a smaller width than the metal reservoir portion, as viewed from a direction perpendicular to a direction in which the pair of window portions overlap each other.

6. The atom cell according to claim 2,
wherein the body portion and the window portion are heated and bonded to each other.

7. The atom cell according to claim 2,
wherein the body portion includes silicon.

8. The atom cell according to claim 1,
wherein a distance between the light passage portion and the metal reservoir portion along the connection portion is greater than the width of the connection portion.

9. The atom cell according to claim 8,
wherein the distance between the light passage portion and the metal reservoir portion along the connection portion is equal to or greater than two times the width of the connection portion.

10. A quantum interference device comprising the atom cell according to claim 1.

11. An atomic oscillator comprising the atom cell according to claim 1.

12. An electronic apparatus comprising the atom cell according to claim 1.

13. A moving object comprising the atom cell according to claim 1.
